(19) United States
(12) Patent Application Publication
(10) Pub. No.: US 2012/0032250 A1
(43) Pub. Date: Feb. 9, 2012

(54) SEMICONDUCTOR DEVICES

(75) Inventors: Yong-Hoon SON, Yongin-si (KR); Sung-Min HWANG, Seoul (KR); Kihyun HWANG, Seongnam-si (KR); Jaehoon JANG, Seongnam-si (KR)

(73) Assignee: Samsung Electronics Co., Ltd.

(21) Appl. No.: 13/182,269

(22) Filed: Jul. 13, 2011

(30) Foreign Application Priority Data
Jul. 13, 2010 (KR) 10-2010-0067528

(51) Int. Cl. H01L 29/792

(52) U.S. Cl. 257/324; 257/E29.309

(57) ABSTRACT

A semiconductor device can include a first substrate and conductive patterns on the first substrate, where the conductive patterns are disposed in stacks vertically extending from the substrate. An active pillar can be on the first substrate vertically extend from the first substrate through the conductive patterns to provide vertical string transistors on the first substrate. A second substrate can be on the conductive patterns and the active pillar opposite the first substrate. A peripheral circuit transistor can be on the second substrate opposite the first substrate, where the peripheral circuit transistor can be adjacent to and overlap an uppermost pattern of the conductive patterns.

### CROSS-REFERENCE TO RELATED APPLICATIONS

This U.S. non-provisional patent application claims priority under 35 U.S.C. §119 of Korean Patent Application No. 10-2010-0067528, filed on Jul. 13, 2010, the entire content of which is hereby incorporated herein by reference.

### BACKGROUND

The present disclosure herein relates to semiconductor devices and methods for fabricating the same, and more particularly, to three-dimensional semiconductor devices and methods for fabricating the same.

3D semiconductor memory devices can include memory cells which are arranged in three dimensions. Mass production of 3D semiconductor memory device still should provide, however, reliable devices that may be more cost effective to produce than two-dimensional (2D) semiconductor memory devices.

### SUMMARY

Embodiments of the inventive concept provide semiconductor devices. Pursuant to these embodiments, a semiconductor device can include a first substrate and conductive patterns on the first substrate, where the conductive patterns are disposed in stacks vertically extending from the substrate. An active pillar can be on the first substrate vertically extend from the first substrate through the conductive patterns to provide vertical string transistors on the first substrate. A second substrate can be on the conductive patterns and the active pillar opposite the first substrate. A peripheral circuit transistor can be on the second substrate opposite the first substrate, where the peripheral circuit transistor can be adjacent to and overlap an uppermost pattern of the conductive patterns.

In some embodiments according to the inventive concept, the semiconductor device can also include a data storage layer that is disposed between the conductive patterns and the active pillar. In some embodiments according to the inventive concept, the first substrate can include a well region and a source region. In some embodiments according to the inventive concept, the active pillar vertically extend from the well region. In some embodiments according to the inventive concept, the active pillar can include a body part can have an identical conductivity type with the well region, and a drain region can have a different conductivity type than the well region, where the well region and the source region are different conductivity types.

In some embodiments according to the inventive concept, a method for fabricating a semiconductor device can be provided by preparing a first substrate that includes conductive patterns and an active pillar, where the conductive patterns are disposed in a vertical stack and includes interposing insulating patterns between each of the conductive patterns. The active pillar can vertically extend through the conductive patterns. A first interlayer insulating layer can be formed to cover the first substrate having the conductive patterns and the active pillar. A second substrate can be formed on the first interlayer insulating layer, where the second substrate includes a peripheral circuit transistor adjacent to and overlapping an uppermost conductive pattern.

In some embodiments according to the inventive concept, the second substrate can be formed by bonding the second substrate on the first interlayer insulating layer by interposing an adhesive layer between the second substrate and the first interlayer insulating layer. The peripheral circuit transistor can be formed on the second substrate.

In some embodiments according to the inventive concept, a memory device can include a first laterally oriented substrate and strings of memory cell transistors on the first laterally oriented substrate, that vertically extend from the first laterally oriented substrate. A second laterally oriented substrate can be on the strings of memory cell transistors opposite the first laterally oriented substrate and a peripheral circuit transistor can be on the second laterally oriented substrate opposite the first laterally oriented substrate.

In some embodiments according to the inventive concept, the peripheral circuit transistor overlaps at least one of the strings of memory cell transistors. In some embodiments according to the inventive concept, the strings of memory cell transistors can be first strings of memory cell transistors, where the device further includes a second string of memory cell transistors vertically extending from the second laterally oriented substrate and laterally spaced apart from the peripheral circuit transistor opposite the first laterally oriented substrate.

In some embodiments according to the inventive concept, the peripheral circuit transistor can be a first peripheral circuit transistor, where the device further includes a third laterally oriented substrate beneath the first laterally oriented substrate opposite the second laterally oriented substrate. A second peripheral circuit transistor can be on the third laterally oriented substrate and overlap the at least one of the strings of memory cell transistors.

### BRIEF DESCRIPTION OF THE DRAWINGS

FIG. 1 is a schematic circuit diagram illustrating a 3D semiconductor device according to embodiments of the inventive concept;

FIG. 2a is a perspective view illustrating a 3D semiconductor device according to an embodiment of the inventive concept;

FIG. 2b is a magnified view of ‘A’ in FIG. 2a.

FIGS. 3 through 9 are process perspective views illustrating a method for fabricating a 3D semiconductor device according to an embodiment of the inventive concept;

FIG. 10 is a perspective view illustrating a 3D semiconductor device according to another embodiment of the inventive concept;

FIG. 11 is a perspective view illustrating a 3D semiconductor device and a method for fabricating the same according to another embodiment of the inventive concept;

FIG. 12 through 16 are schematic cross-sectional views illustrating 3D semiconductor device according to other embodiments of the inventive concept;

FIG. 17 is a schematic block diagram illustrating a memory system including a 3D semiconductor device according to embodiments of the inventive concept;

FIG. 18 is a schematic block diagram illustrating a memory card including a 3D semiconductor device according to embodiments of the inventive concept; and

FIG. 19 is a schematic block diagram illustrating a data processing system including a 3D semiconductor device according to embodiments of the inventive concept.

### DETAILED DESCRIPTION OF EMBODIMENTS ACCORDING TO THE INVENTIVE CONCEPT

Exemplary embodiments of the inventive concept will be described below in more detail with reference to the accompanying drawings. The embodiments of the inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will be understood that the term “3D” is sometimes used herein to refer to vertically oriented strings of memory cell transistors (such as vertical NAND strings) on a laterally oriented substrate so that the string extends in a direction that is perpendicular to the lateral surface of the substrate.

Hereinafter, exemplary embodiments of the inventive concept will be described in detail with reference to the accompanying drawings.

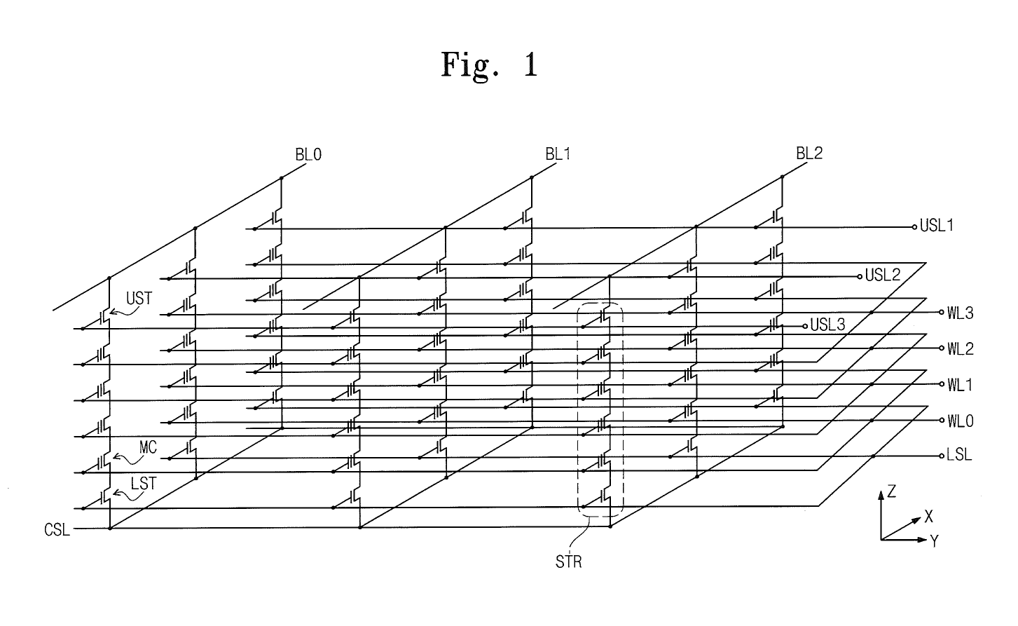

FIG. 1 is a schematic circuit diagram illustrating a 3D semiconductor device according to embodiments of the inventive concept.

Referring to FIG. 1, a 3D semiconductor device according to an embodiment of the inventive concept includes a cell array having a plurality of strings STR. The cell array may include a plurality of bit lines BL0˜BL2, a plurality of word lines WL0˜WL3, upper and lower selection lines USL1˜USL3 and LSL, and a common source line CSL. The plurality of strings STR may be included between the bit lines BL0˜BL2 and the common source line CSL.

Each of the strings STR may include upper and lower selection transistors UST and LST, and a plurality of memory cell transistors MC serially connected between the upper selection transistor UST and the lower selection transistor LST. Drains of the upper selection transistors UST may be connected to the bit lines BL0˜BL2, and sources of the lower selection transistors LST may be connected to the common source line CSL. The common source line CSL may be a line which is connected in common with the sources of the lower selection transistors LST.

The upper selection transistors UST may be connected to the upper selection lines USL1˜USL3, and the lower selection transistors LST may be connected to the lower selection line LSL. Each of the memory cell transistors MC may be connected to the word lines WL0˜WL3.

The cell array is arranged in structure of three dimensions such that the strings STR include the memory cell transistors MC serially connected in a direction of a Z-axis. The Z-axis is perpendicular with an X-Y plane which is parallel with an upper surface of a substrate. Thus channels of the upper and lower selection transistors UST and LST and memory cell transistors MC may be perpendicular with the X-Y plane.

In the semiconductor device having structure of three dimensions, memory cells to the number of m may be provided at each X-Y plane, the X-Y planes to the number of n may be stacked in the direction of the Z-axis (here, m and n are natural numbers).

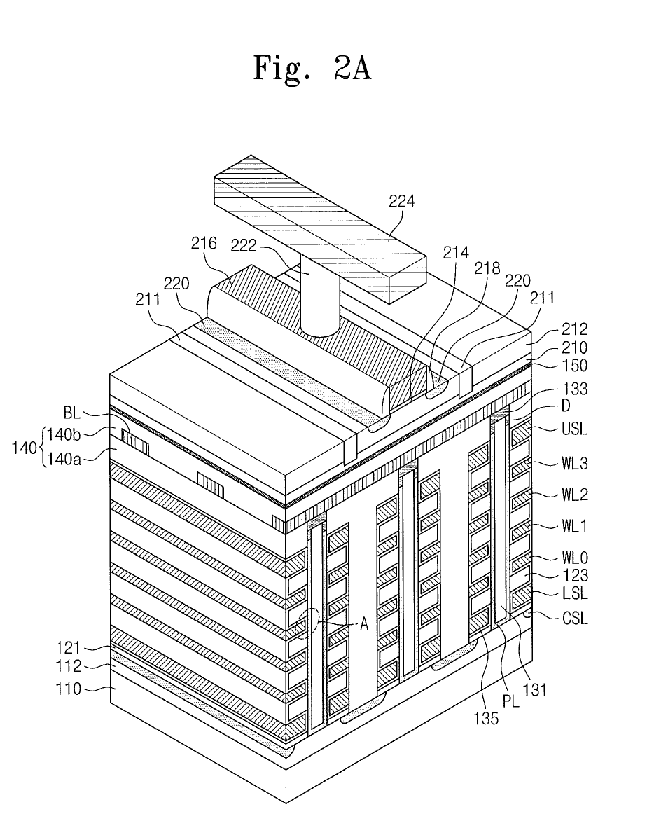

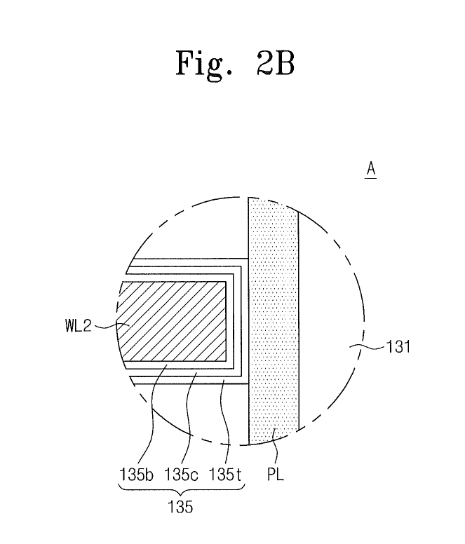

FIG. 2a is a perspective view illustrating a 3D semiconductor device according to an embodiment of the inventive concept; and FIG. 2b is a magnified view of ‘A’ in FIG. 2a.

Referring to FIGS. 2a and 2b, a buffer dielectric layer 121 may be provided on a first substrate 110. A well region 112 having a first conductivity type may be provided in the first substrate 110. The buffer dielectric layer 121 may be formed of silicon oxide (SiO₂). Insulating patterns 123 and conductive patterns LSL, WL0˜WL3 and USL may be provided on the buffer dielectric layer 121 such that the conductive patterns are spaced apart from each other with the insulating pattern 123 interposed between each conductive pattern.

The conductive patterns LSL, WL0˜WL3 and USL may include a lower selection line LSL, an upper selection line USL and word lines WL0˜WL3 between the lower selection line LSL and the upper selection line USL. The conductive patterns LSL, WL0˜WL3 and USL may have line shape extending in a first direction parallel with the first substrate 110. The conductive patterns LSL, WL0˜WL3 and USL may include at least one of doped silicon, tungsten (W), metal nitride and metal silicide.

A plurality of active pillars PL may be provided through the conductive patterns LSL, WL0˜WL3 and USL. The active pillars PL may be connected with the first substrate 110. The active pillars PL may have the major axis extending upward from the first substrate 110. Thus, the major axis may extend in a third direction. The active pillars PL may include semiconductor material. The active pillar PL may be formed into solid cylinder type or such that the centers are hollow cylinder type (such as macaroni type). Centers of the active pillars PL of the macaroni type may be filled with an insulating material. The insulating material filling the centers of the active pillars PL of the macaroni type may be a filling insulating layer 131. In one aspect according to an embodiment of the inventive concept, the active pillars PL and the first substrate 110 may be a semiconductor of continuous structure. The active pillars PL may be formed of single crystalline semiconductor. In another aspect according to an embodiment of the inventive concept, the active pillars PL and the first substrate 110 may have a discontinuous interface. The active pillars PL may be formed of poly crystalline semiconductor or amorphous semiconductor. Each active pillar PL may include a body part which is adjacent to the first substrate 110 and a drain region D which is disposed at an upper portion of each active pillar PL spaced apart from the first substrate 110. The body part may have the first conductivity type, but the drain region D may have a second conductivity type different from the first conductivity type.

An end of each active pillar PL, for example the body part, may be connected with the first substrate 110, and the other end of each active pillar PL, for example the drain region D, may be connected with a bit line BL. A capping semiconductor pattern 133 may be disposed between the bit line BL and each active pillar PL. The capping semiconductor pattern 133 may have the second conductivity type the same as the drain region D has. The bit line BL may extend in a second direction crossing the first direction. Each active pillar PL may be connected with one bit line BL such that one bit line BL may be connected with a plurality of strings STR of FIG. 1. The active pillars PL may be arranged on a plane in two dimensions such as a matrix arrangement. The plane may be defined by the first and second directions. Thus intersection points between the word lines WL0˜WL3 and the active pillars PL may be arranged in three dimensions. Memory cells MC of FIG. 1 of the 3D semiconductor device according to the inventive concept may be provided at the intersection points which are arranged in three dimensions. Therefore, a memory cell may be determined by one active pillar PL and one word line WL0, WL1, WL2 or WL3.

A data storage layer 135 may be provided between the word lines WL0˜WL3 and the active pillars PL. The data storage layer 135 may extend on top and bottom surfaces of the word lines WL0˜WL3. The data storage layer 135 may include a blocking insulating layer 135b adjacent to the word lines WL0˜WL3, a tunnel insulating layer 135t adjacent to the active pillars PL and a charge storage layer 135c between the blocking insulating layer 135b and the tunnel insulating layer 135t. The blocking insulating layer 135b may include a high-k dielectric layer, for example, an aluminum oxide layer or a hafnium oxide layer. The blocking insulating layer 135b may be formed into a multilayer which has a plurality of thin layers. For example, the blocking insulating layer 135b may include an aluminum oxide layer and a silicon oxide layer. The aluminum oxide layer and the silicon oxide layer may be stacked in various orders. The charge storage layer 135c may be a charge trap layer or a conductive nanoparticle containing insulating layer. The charge trap layer may include a layer such as a silicon nitride layer. The tunnel insulating layer 135t may include a silicon oxide layer.

The 3D semiconductor device according to the inventive concept may be a NAND flash memory device in which memory cells provided at one active pillar compose one cell string.

The conductive patterns LSL, WL0˜WL3 and USL may be stacked to have stair step structure at least on one end. For example, a conductive pattern may extend beyond an end of the right above conductive pattern to have an exposed upper surface by the above conductive pattern. In comparing two conductive patterns in the stair step structure, the area is smaller in the conductive pattern far from the first substrate 110 than the conductive pattern close to the first substrate 100. A first interlayer insulating layer 140 may be provided to cover the conductive patterns LSL, WL0˜WL3 and USL of the stair step structure and the bit lines BL. The first interlayer insulating layer 140 may include a lower first interlayer insulating layer 140a and an upper first interlayer insulating layer 140b. The lower first interlayer insulating layer 140a may cover the conductive patterns LSL, WL0˜WL3 and USL of the stair structure and may be disposed between the conductive patterns LSL, WL0˜WL3 and USL adjacent to each other in the second direction, and the upper first interlayer insulating layer 140b may cover the bit lines BL. The first interlayer insulating layer 140 may be formed of silicon oxide. A common source line CSL may be provided in the well region 112 which is disposed under the first interlayer insulating layer 140. The common source line CSL may have the second conductivity type.

A second substrate 210 may be provided on the first interlayer insulating layer 140 with an adhesive layer 150 interposed therebetween. The second substrate 210 may include a transistor for a peripheral circuit. A device isolation layer 211 and a well region 212 may be disposed in the second substrate 210. A plurality of transistors having various functions for the peripheral circuit may be disposed on the second substrate 210. The transistor may include a gate insulating layer 214, a gate electrode 216 and a spacer 218. Impurity regions 220 may be provided in the second substrate 210 at both sides of the gate electrode 216 to provide a source and a drain of the transistor.

The transistor may be electrically connected to at least one of the bit lines BL0˜BL2, the word lines WL0˜WL3, the upper and lower selection lines USL1˜USL3 and LSL, and the common source line CSL to control operation thereof.

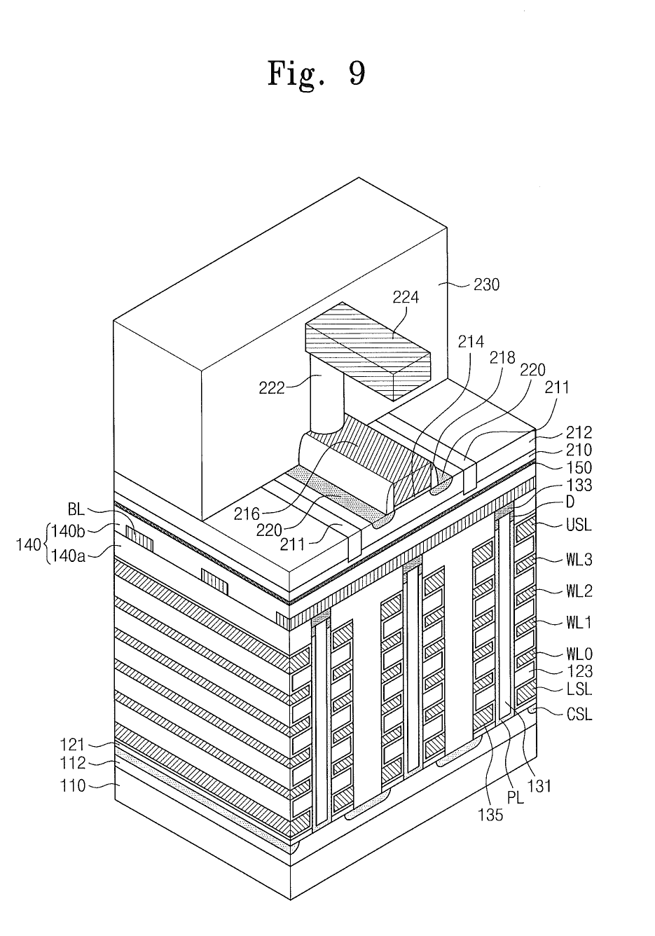

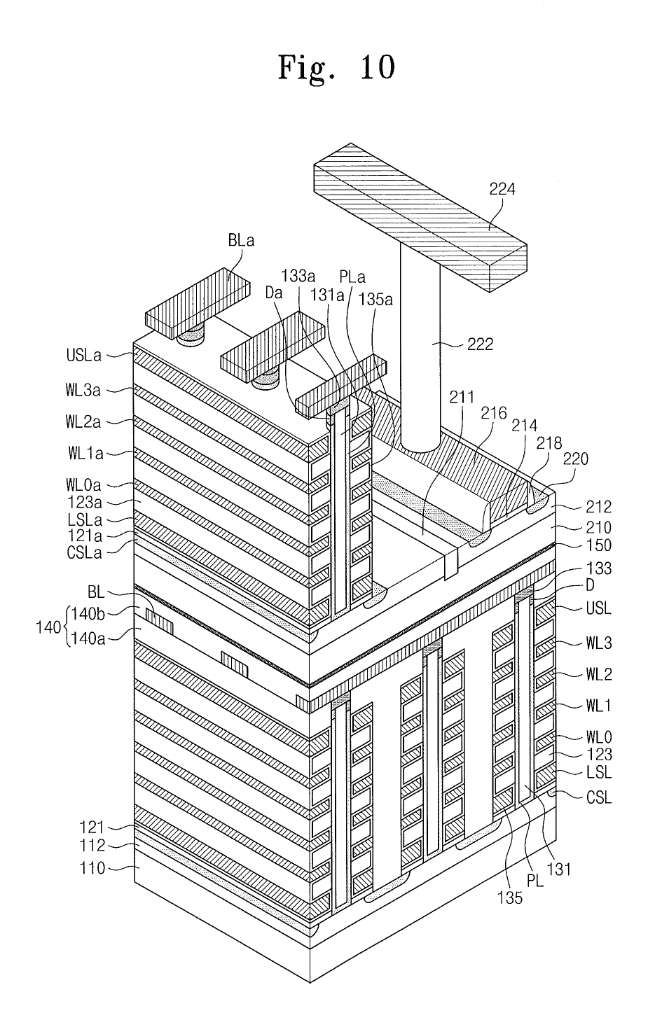

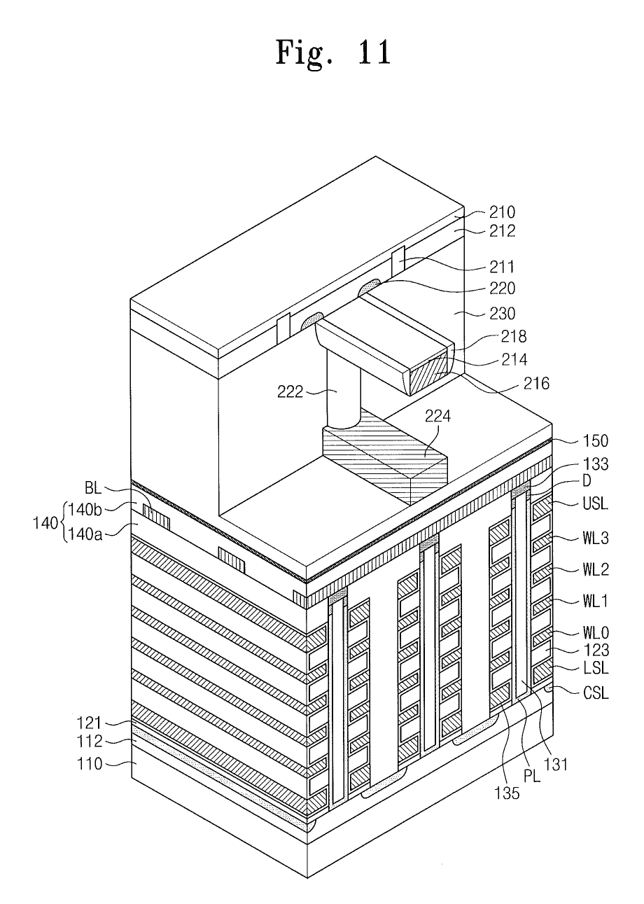

A contact plug 222 is connected with the transistor and a metal line 224 is connected with the contact plug 222. A second interlayer insulating layer 230 of FIG. 9 or 11 may be provided to cover the transistor, the contact plug 222 and the metal line 224.

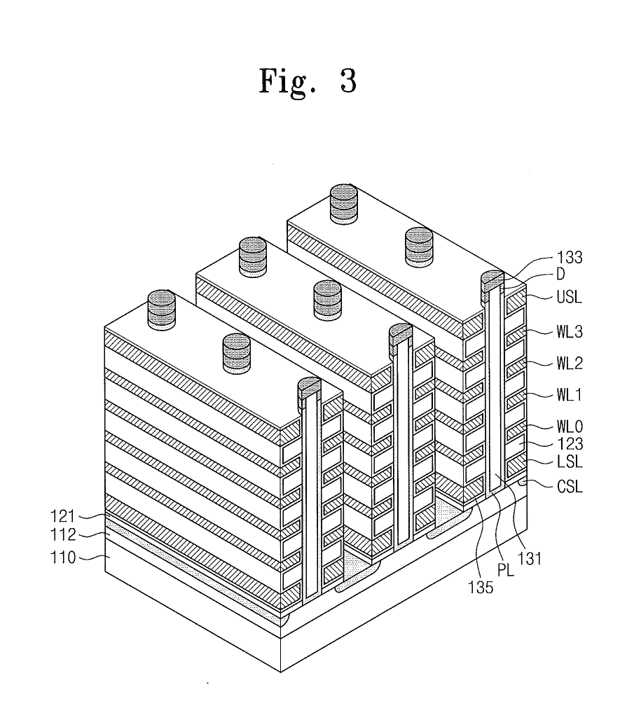

FIGS. 3 through 9 are process perspective views illustrating a method for fabricating a 3D semiconductor device according to an embodiment of the inventive concept.

Referring to FIG. 3, a first substrate 110 is prepared. The first substrate 110 may have conductive patterns LSL, WL0˜WL3 and USL which are disposed in a stack with an insulating pattern 123 interposed between each conductive pattern, and active pillars PL which extend vertically through the conductive patterns LSL, WL0˜WL3 and USL.

The first substrate 110 may further include a well region 112 which is formed in the first substrate 110 and a common source line CSL which is disposed in the well region 112. The well region 112 may have a first conductivity type and the common source line CSL may have a second conductivity type. The active pillars PL may vertically extend from the well region 112. A data storage layer 135 may be disposed between the conductive patterns LSL, WL0˜WL3 and USL and the active pillars PL.

The active pillars PL may have the major axis which extends upward from a surface of the first substrate 110. The active pillars PL may be formed into solid cylindrical type or such that the centers are hollow cylindrical type (for example, macaroni type). Centers of the active pillars PL of the macaroni type may be filled with insulating material. The insulating material filling the centers of the active pillars PL of the macaroni type may be a filling insulating layer 131. Each active pillar PL may include a body part adjacent to the first substrate 110 and a drain region D on an upper portion spaced apart from the first substrate 110. The body part may have the first conductivity type and the drain region D may have the second conductivity type which is different from the first conductivity type.

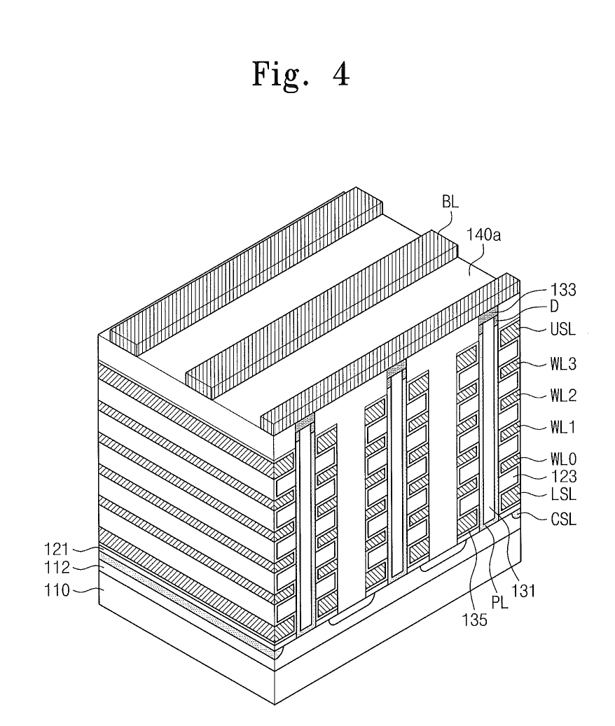

Referring to FIG. 4, a lower first interlayer insulating layer 140a may be formed to fill a space between laterally adjacent the conductive patterns LSL, WL0˜WL3 and USL. Bit lines BL are then formed to connect the drain regions D.

Thus, an end of each active pillar PL, i.e. the body part may be connected to the first substrate 110 and the other end of each active pillar PL, i.e. the drain region D may be connected to the bit line BL. A capping semiconductor pattern 133 may be disposed between the bit line BL and the other end of each active pillar PL, i.e. the drain region D. The capping semiconductor pattern 133 may have the second conductivity type the same as the drain region D has. The bit lines BL may extend in a direction which crosses over the extending direction of the conductive patterns LSL, WL0˜WL3 and USL. Each active pillar PL may be connected to one bit line BL such that one bit line BL may be connected with a plurality of strings STR of FIG. 1.

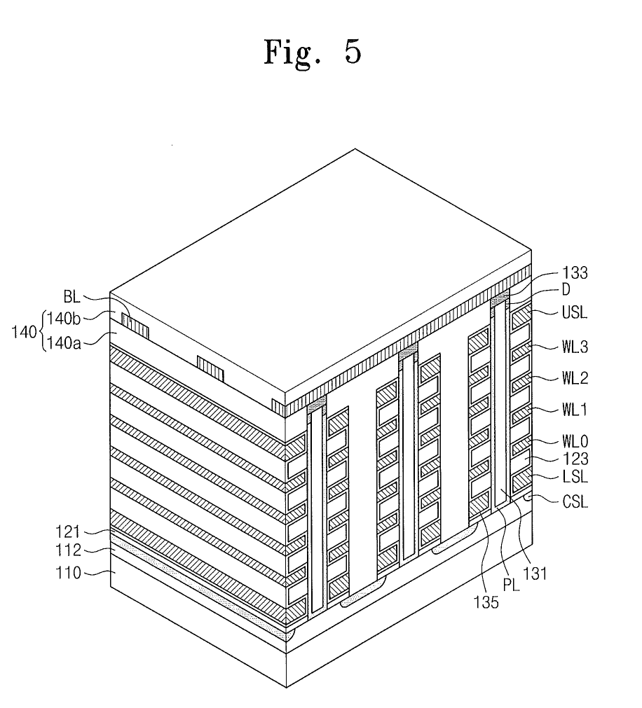

Referring to FIG. 5, an upper first interlayer insulating layer 140b may be formed to cover the bit lines BL. The lower first interlayer insulating layer 140a and the upper first interlayer insulating layer 140b are designated together as a first interlayer insulating layer 140.

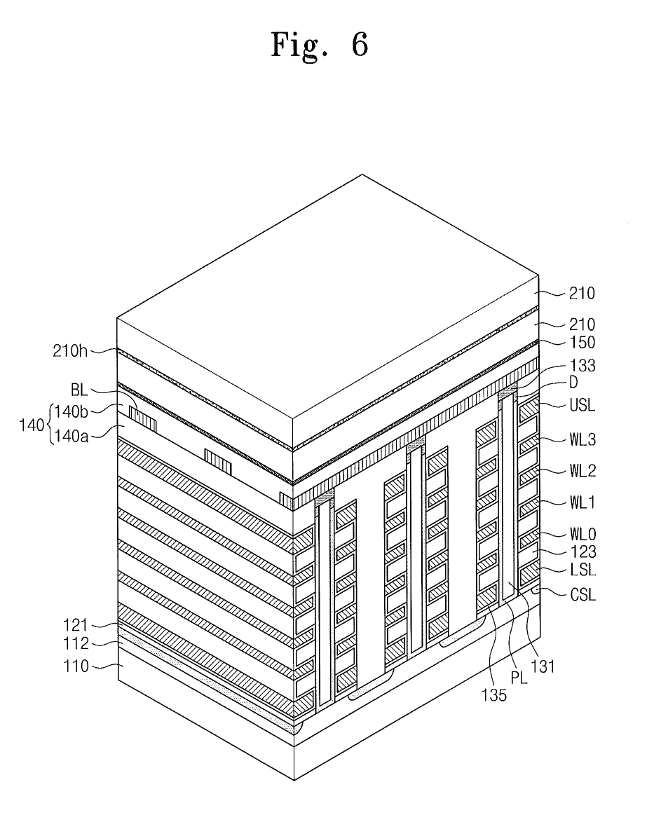

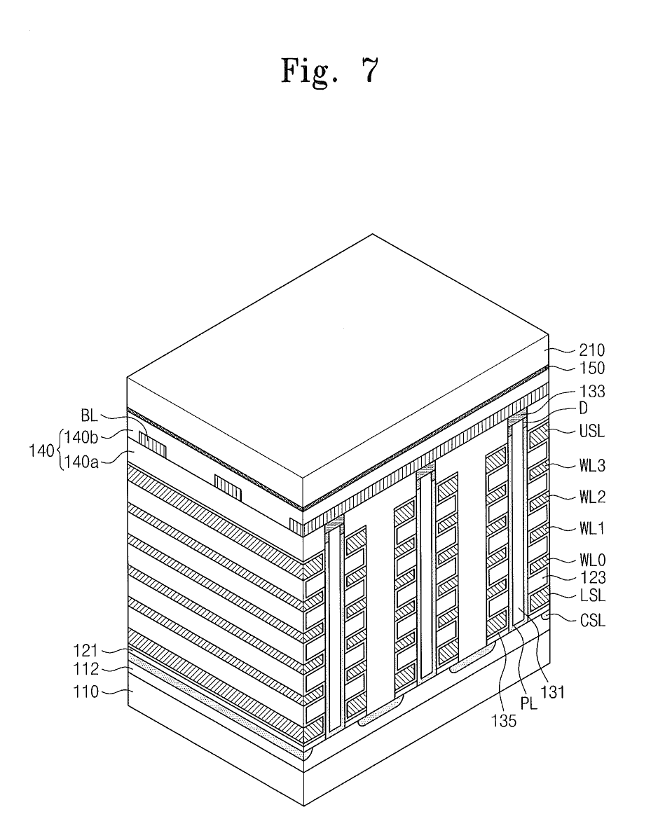

Referring to FIGS. 6 and 7, a second substrate 210 may be formed on the first interlayer insulating layer 140 by interposing an adhesive layer 150. The forming of the second substrate 210 on the first interlayer insulating layer 140 by interposing the adhesive layer 150 may include bonding the second substrate 210 on the first interlayer insulating layer 140 by interposing the adhesive layer 150, forming a hydrogen ion implantation layer 210h in the second substrate 210, and removing the hydrogen ion implantation layer 210h and the second substrate 210 on the hydrogen ion implantation layer 210h. Alternatively, the forming of the second substrate 210 on the first interlayer insulating layer 140 by interposing the adhesive layer 150 may include bonding the second substrate 210 having a hydrogen ion implantation layer 201h on the first interlayer insulating layer 140 by interposing the adhesive layer 150, and then removing the hydrogen ion implantation layer 210h and the second substrate 210 on the hydrogen ion implantation layer 210h.

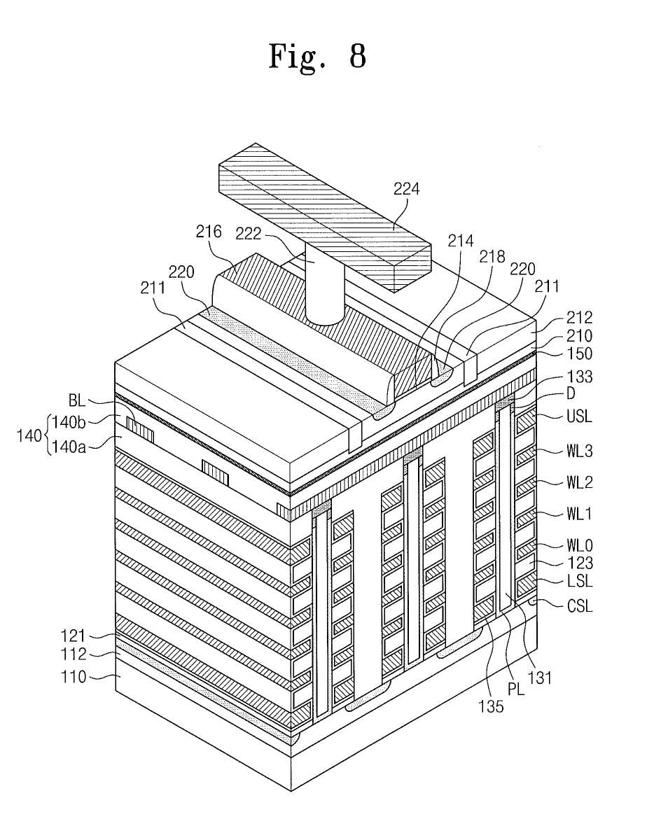

Referring to FIGS. 8 and 9, after forming a device isolation layer 211 and a well region 212 of the first conductivity type, a transistor for a peripheral circuit is formed on the second substrate 210. A plurality of transistors for the peripheral circuit having various functions may be formed on the second substrate 210. The transistor may include a gate insulating layer 214, a gate electrode 216 and a spacer 218. Impurity regions 220 of the second conductivity type may be provided in the well region 212 at both sides of the gate electrode 216 to serve source and drain electrodes of the transistor.

A contact plug 222 connected to the transistor and a metal line 224 connected to the contact plug 222 may be formed. A second interlayer insulating layer 230 may be formed to cover the transistor, the contact plug 222 and the metal line 224 may be further formed. FIG. 9 is a drawing on which a portion of the second interlayer insulating layer 230 for illustrating the transistor, the Contact plug 222 and the metal line 224 which are formed on the second substrate 210.

Therefore, the 3D semiconductor device according to the inventive concept has a structure that the second substrate 210 including transistors for the peripheral circuit is disposed on the first substrate 110 with the adhesive layer 150 interposed therebetween such that the first interlayer insulating layer 140 and the second substrate 210 are adjacent with each other.

FIG. 10 is a perspective view illustrating a 3D semiconductor device according to another embodiment of the inventive concept.

Referring to FIG. 10, in a 3D semiconductor device according to another embodiment of the inventive concept, a second substrate 210 including a transistor for the peripheral circuit may have upper conductive patterns LSLa, WL0a˜WL3a and USLa which are disposed in a stack by at least one side of a transistor and upper active pillars PLa which extends vertically through the upper conductive patterns LSLa, WL0a˜WL3a and USLa. The upper conductive patterns LSLa, WL0a˜WL3a and USLa may be disposed in a stack with an upper insulating pattern 121a interposed each conductive pattern.

The second substrate 210 may further include a device isolation layer 211 and a well region 212 therein. The second substrate 210 may further include a common source line CSLa in the well region 212. The upper active pillars PLa may extend vertically from the well region 212. A data storage layer 135a may be formed between the upper conductive patterns LSLa, WL0a˜WL3a and USLa and the upper active pillars PLa.

The upper active pillars PLa may have the major axis extending upward from a surface of the second substrate 210. The upper active pillars PLa may be formed into solid cylinder type or such that the centers are hollow cylinder type (for example, macaroni type). Centers of the upper active pillars PLa of the macaroni type may be filled with insulating material. The insulating material filling the centers of the upper active pillars PLa of the macaroni type may be a filling insulating layer 131a. Each upper active pillar PLa may have a body part which is adjacent to the second substrate 210 and a drain region Da which is formed at an upper portion of each upper active pillar PLa spaced apart from the second substrate 210.

An end of each upper active pillar PLa i.e., the body part may be connected with the second substrate 210 and the other end of each upper active pillar PL i.e., the drain region Da may be connected with a bit line BLa. A capping semiconductor pattern 133a may be disposed between the bit line BLa and each upper active pillar PLa. The bit line BLa may extend crossing over the extending direction of the upper conductive patterns LSLa, WL0a˜WL3a and USLa. Each upper active pillar PL is connected with one bit line BLa such that one bit line BLa may be connected with a plurality of strings STR of FIG. 1.

Consequently, the 3D semiconductor device according to this embodiment of the inventive concept further include the conductive patterns LSLa, WL0a˜WL3a and USLa which are disposed in a stack by at least one side of the transistor on the second substrate 210 with an insulating pattern 123a interposed between each conductive pattern, and the active pillars PLa which extend vertically through the conductive patterns LSLa, WL0a˜WL3a and USLa. Thus, the 3D semiconductor device according to this embodiment can be further improved in the memory storage capacity.

FIG. 11 is a perspective view illustrating a 3D semiconductor device and a method for fabricating the same according to another embodiment of the inventive concept.

Referring to FIG. 11, a 3D semiconductor device according to further another embodiment of the inventive concept has a different structure from the 3D semiconductor device of FIG. 9. The 3D semiconductor device according to this embodiment include a second substrate 210 disposed on a first substrate 110. The second substrate 210 includes a transistor for a peripheral circuit. The first substrate 110 includes conductive patterns LSL, WL0˜WL3 and USL which are sequentially disposed in a stack and spaced apart from each other by an insulating pattern 123 interposed between each conductive pattern. The first substrate 110 further includes active pillars PL which extend vertically through the conductive patterns LSL, WL0˜WL3 and USL.

The first substrate 110 and the second substrate 210 may be individually prepared. A second interlayer insulating layer 230 is formed to cover the second substrate 210 including the transistor, and the second substrate 210 is then bonded on the first substrate 110 such that a first interlayer insulating layer 140 is adjacent to the second interlayer insulating layer 230 with an adhesive layer 150 interposed between the first and second interlayer insulating layers 140 and 230.

Consequently, in the 3D semiconductor device according to this embodiment, the second substrate 210 including the transistor for the peripheral circuit may be provided on the first substrate 110 by interposing the adhesive layer 150 such that the first interlayer insulating layer 140 and the second interlayer insulating layer 230 are adjacent to each other.

FIGS. 12 through 16 are schematic cross-sectional views illustrating 3D semiconductor device according to other embodiments of the inventive concept, respectively.

Referring to FIG. 12, contrary to the 3D semiconductor device of FIG. 9, a 3D semiconductor device according to still another embodiment of the inventive concept further includes a third substrate 310 which is disposed under a first substrate 110 with an adhesive layer 250 interposed between the first substrate 110 and the third substrate 310. The first substrate 110 has a 3D memory cell array region CR and the third substrate 310 has a transistor for a peripheral circuit.

Referring to FIGS. 13 through 15, 3D semiconductor devices according to still other embodiments of the inventive concept may include a transistor for a peripheral circuit which is disposed by at least one side of a 3D memory cell array region CR on a first substrate 110.

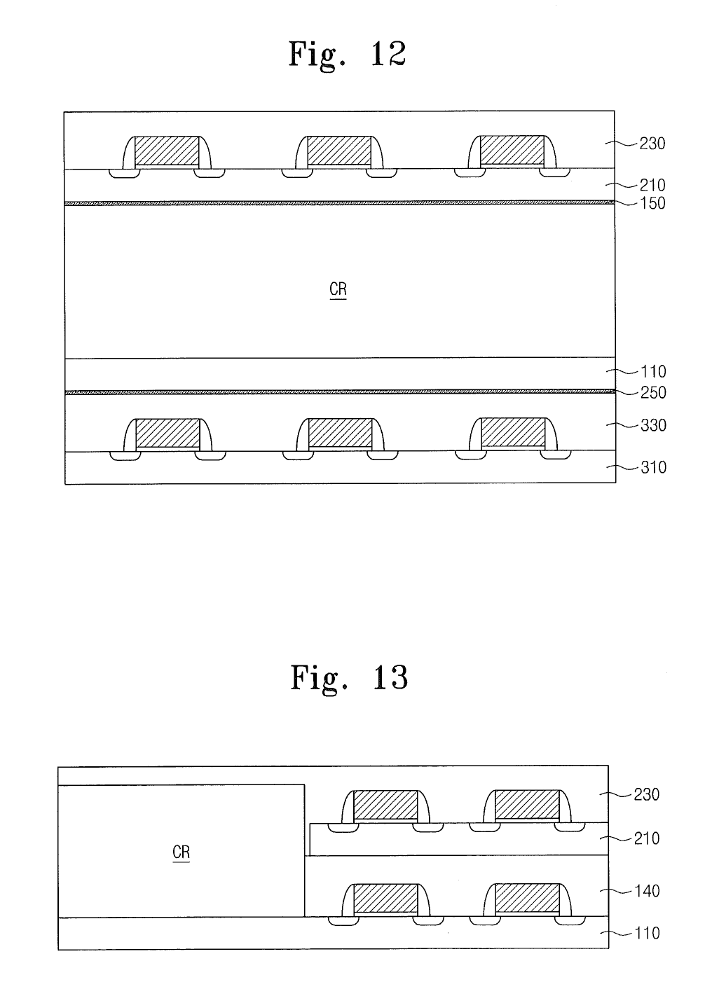

FIG. 13 shows a 3D structural peripheral circuit in which a second substrate 210 is disposed below an upper surface of a 3D memory cell array region CR such that a peripheral circuit is formed on the second substrate 210.

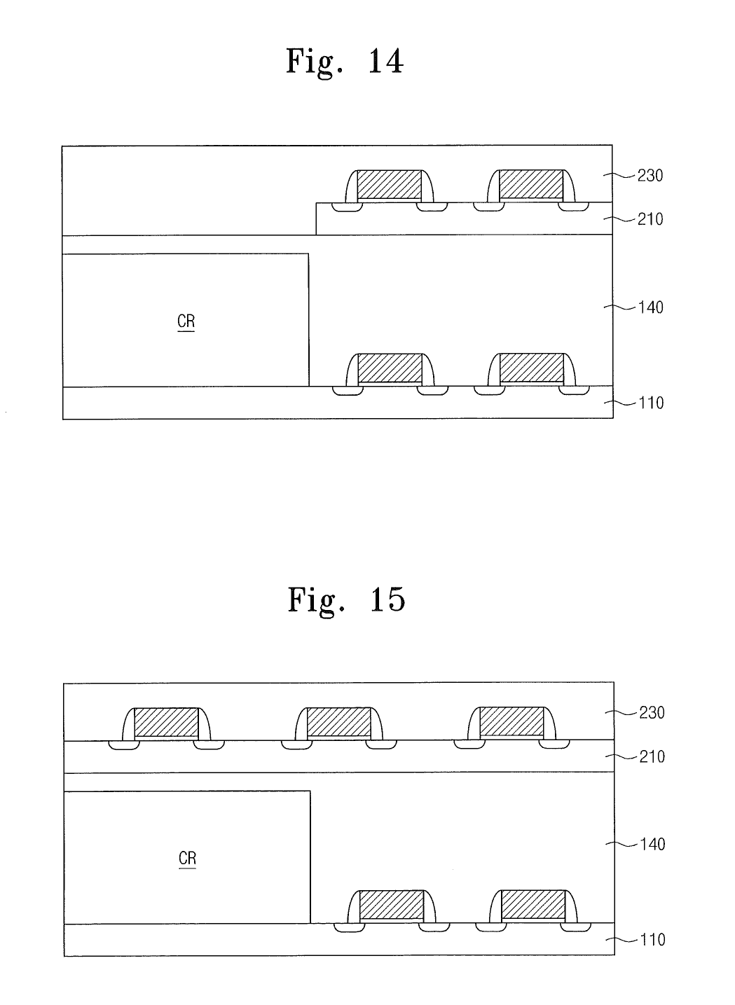

Each of FIGS. 14 and 15 shows a 3D structural peripheral circuit in which a second substrate 210 is disposed above an upper surface of a 3D memory cell array region CR such that a peripheral circuit is formed on the second substrate 210.

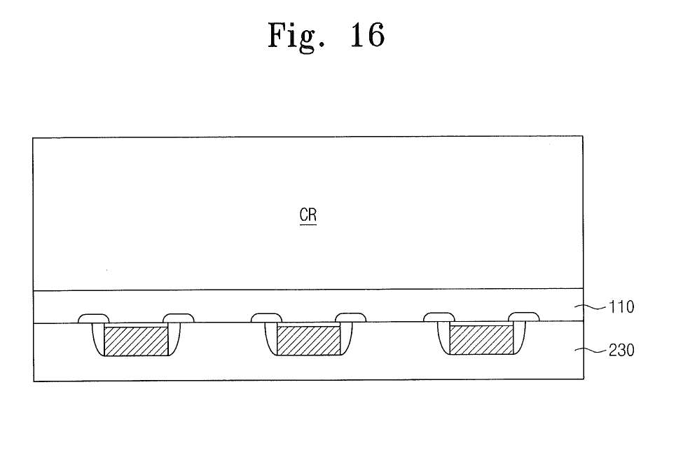

Referring to FIG. 16, a 3D semiconductor device according to still another embodiment of the inventive concept may include a transistor for a peripheral circuit on a rear surface of a first substrate 110 which includes a 3D memory cell array region CR on a front surface.

According to these embodiments, the second substrate having the transistor for the peripheral circuit is disposed on the first substrate where the conductive patterns are disposed in a stack with the insulating pattern interposed between each conductive pattern and the active pillars vertically extend through the conductive patterns. Thus, 3D semiconductor devices can be provided without improving or by reducing an area of the semiconductor device.

Although a 3D NAND flash memory cell array is served as an example of the 3D semiconductor device, a variety structures of a 3D memory cell array can be acceptable to embodiments of the inventive concept.

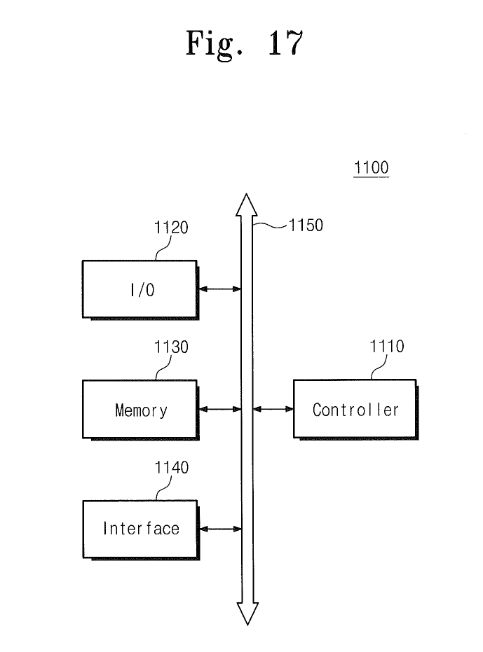

FIG. 17 is a schematic block diagram illustrating a memory system including a 3D semiconductor device according to embodiments of the inventive concept.

Referring to FIG. 17, memory system 1100 is applicable to a personal digital assistant (PDA), a portable computer, a web tablet, a wireless phone, a mobile phone, a digital music player, a memory card or applications capable of transmitting and/or receiving information in environment.

The memory system 1100 includes a controller 1110, input/output devices 1120 such as a key pad, a key board and display, memory 1130, an interface 1140 and a bus 1150. The memory 1110 and the interface 1140 communicate each other through the bus 1150.

The controller 1110 includes at least one of a microprocessor, a digital signal processor, a microcontroller, or other processing devices. The memory 1130 stores commands that are processed by the controller 1110. The input/output device 1120 is used to receive data or signal from outside, and send data or signal from the system 1100.

The memory 1130 includes a non-volatile memory device according to embodiments of the inventive concept. The memory 1130 may further include a memory that is accessible at any time, and other sort of memories.

The interface 1140 transmits data to a network or receives data from a network.

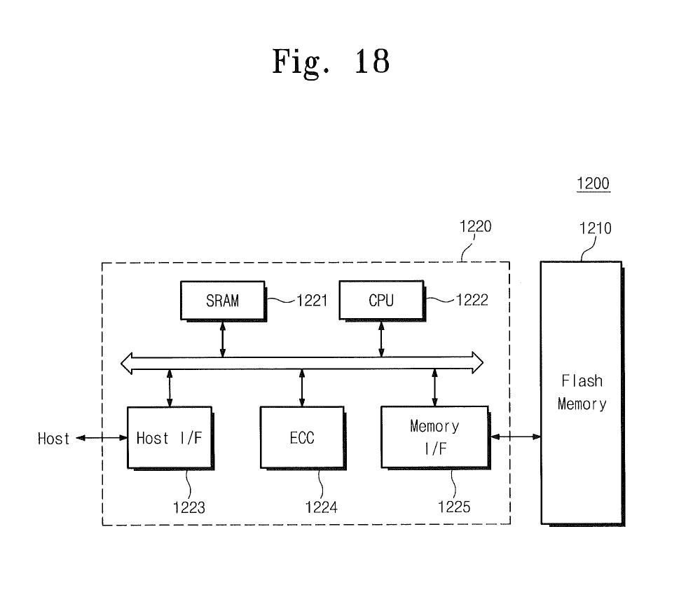

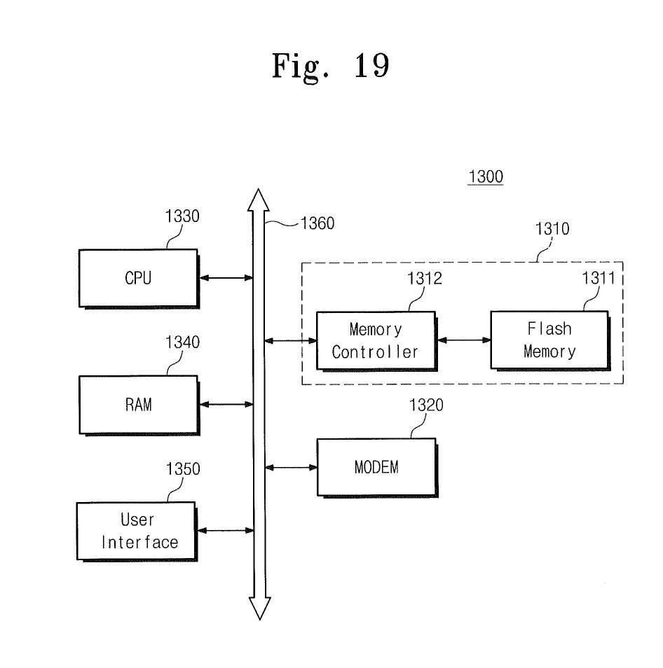

FIG. 18 is a block diagram illustrating a memory card that includes a non-volatile memory device according to embodiments of the inventive concept.

Referring to FIG, 18, memory card 1200 supporting a mass storage incorporates a memory device 1210 including a 3D semiconductor device according to embodiments of the inventive concept. The memory card 1200 according to embodiments of the inventive concept includes a memory controller 1220 that manages data exchange between a host and the non-volatile memory device 1210.

SRAM (Static Random Access Memory) 1221 is used as an operating memory for CPU (Central Processing Unit) 1222. Host interface 1223 includes data exchange protocol of the host connected with the memory card 1200. Error correction coding (ECC) block 1224 detects and corrects error that is included in read data from the memory device 1210 with multi bit characteristic. Memory interface 1225 interfaces with the memory device 1210 including the 3D semiconductor device according to the inventive concept. The CPU manages the memory controller to exchange data. The memory device may further include ROM (Read Only Memory) that stores code data for interfacing with the host.

According to embodiments of the inventive concept, a memory system with high integration can be provided. The 3D semiconductor device according to embodiments of the inventive concept is applicable to a memory system such as solid state drive (SSD), thereby provides a memory system with high integration.

FIG. 19 is a block diagram illustrating a data processing system that includes a 3D semiconductor device according to embodiments of the inventive concept.

Referring to FIG. 19, a memory system 1310 may be embedded in a data processing system 1300 such as a mobile device or a desktop computer. The memory system 1310 may include the semiconductor device 1311 according to the inventive concept and a memory controller for exchanging data between a system bus 1360 and the semiconductor device 1311. The data processing system 1300 includes a modem 1320, a CPU 1330, a RAM 1340 and a user interface that are electrically connected with a bus 1360, respectively. The memory system 1310 may be the memory system described in FIG. 17. Data processed by the CPU 1330 or input from outside world is stored in the memory system 1310. The memory system may a solid state drive. Thus the data processing system can store stably a mass of data in the non-volatile memory system 1310. If reliability is enhanced, the non-volatile memory device 1310 can reduced resource for correcting error and can provide high data exchanging performance to the data processing system 1300. It is obvious for a person who is skilled in the field of present invention that the data processing system 1300 according to embodiments of present invention may further include a application chipset, an image signal process (ISP), and an input/output device.

The non-volatile memory device or memory system according to embodiments of the present invention may be embedded into various packages, such as a PoP (Package on Package), a BGAs (Ball Grid Arrays), a CSPs (Chip Scale Packages), a PLCC (Plastic Leaded Chip Carrier), a PDIP (Plastic Dual In-line Package), a die in waffle pack, a die in wafer form, a COB (Chip On Board), a CERDIP (CERamic Dual In-line Package), a MQFP (plastic Metric Quad Flat Pack), a TQFP (Thin Quad Flat Pack), a SOIC (Small-Outline Integrated Circuit), a SSOP (Shrink Small-Outline Package), a TSOP (Thin Small Outline Package), a SIP (System In Package), a TQFP (Thin Quad Flat Pack), a MCP (Multi Chip Package), a WFP (Wafer-level Fabricated Package) or a WSP (Wafer-level processed Stack Package).

As described above, according to embodiments of the inventive concept, the 3D semiconductor device includes a first substrate and a second substrate disposed on the first substrate. The first substrate has conductive patterns which are stacked with interposing insulating pattern therebetween and active pillars which extend vertically through the conductive patterns. The second substrate has transistors for a peripheral circuit. Thus the semiconductor device has relatively small area or can reduce area. Therefore, the 3D semiconductor device can be provided to have relative high density memory storage without increasing the area of the semiconductor device.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1. A semiconductor device, comprising:
a first substrate;
conductive patterns on the first substrate, the conductive patterns disposed in stacks vertically extending from the substrate;
an active pillar on the first substrate vertically extending from the first substrate through the conductive patterns to provide vertical string transistors on the first substrate;
a second substrate on the conductive patterns and the active pillar opposite the first substrate; and
a peripheral circuit transistor on the second substrate opposite the first substrate, wherein the peripheral circuit transistor is adjacent to and overlapping an uppermost pattern of the conductive patterns.

2. The semiconductor device of claim 1, further comprising:
a data storage layer disposed between the conductive patterns and the active pillar.

3. The semiconductor device of claim 1, wherein the first substrate further comprises a well region and a source region.

4. The semiconductor device of claim 3, wherein the active pillar vertically extend from the well region.

5. The semiconductor device of claim 4, wherein the active pillar comprise a body part having an identical conductivity type with the well region, and a drain region having a different conductivity type than the well region,
wherein the well region and the source region are different conductivity types.

6. The semiconductor device of claim 1, further comprising:
a first interlayer insulating layer on the first substrate covering the conductive patterns and the active pillar;
a second interlayer insulating layer on the second substrate covering the peripheral circuit transistor; and
an adhesive layer interposed between the second substrate and the first interlayer insulating layer.

7. The semiconductor device of claim 1, wherein the first substrate further comprises a first interlayer insulating layer covering the conductive patterns and the active pillar, and the second substrate further comprises a second interlayer insulating layer covering the transistor; and
an adhesive layer interposed between the first interlayer insulating layer and the second interlayer insulating layer.

8-15. (canceled)

16. A memory device, comprising:
a first laterally oriented substrate;
strings of memory cell transistors on the first laterally oriented substrate, and vertically extending from the first laterally oriented substrate;
a second laterally oriented substrate on the strings of memory cell transistors opposite the first laterally oriented substrate; and
a peripheral circuit transistor on the second laterally oriented substrate opposite the first laterally oriented substrate.

17. The device of claim 16, wherein the peripheral circuit transistor overlaps at least one of the strings of memory cell transistors.

18. The device of claim 17, wherein the strings of memory cell transistors comprise first strings of memory cell transistors, the device further comprising:
a second string of memory cell transistors vertically extending from the second laterally oriented substrate and laterally spaced apart from the peripheral circuit transistor opposite the first laterally oriented substrate.

19. The device of claim 17, wherein the peripheral circuit transistor comprises a first peripheral circuit transistor, the device further comprising:
a third laterally oriented substrate beneath the first laterally oriented substrate opposite the second laterally oriented substrate; and
a second peripheral circuit transistor on the third laterally oriented substrate and overlapping the at least one of the strings of memory cell transistors.

20. The device of claim 17, wherein the peripheral circuit transistor comprises a first peripheral circuit transistor, the device further comprising:
a second peripheral circuit transistor on the second laterally oriented substrate and overlapping the at least one of the strings of memory cell transistors.
